(19) United States
(12) Patent Application Publication
(10) Pub. No.: US 2026/0324524 A1
(43) Pub. Date: Oct. 15, 2026

(54) SENSOR SYSTEM AND IMAGE FORMING APPARATUS

(71) Applicant: CANON KABUSHIKI KAISHA, Tokyo (JP)

(72) Inventors: TAKUYA MIYASHITA, Kanagawa (JP); YUJI ITAKURA, Tokyo (JP); JUNJI SUZUKI, Kanagawa (JP); AKIRA TATSUZUE, Saitama (JP); MASAMICHI IIDA, Kanagawa (JP); HIROSHI FUSE, Tokyo (JP)

(21) Appl. No.: 19/536,611

(22) Filed: Feb. 11, 2026

(30) Foreign Application Priority Data
Apr. 15, 2025 (JP) 2025-066840
Apr. 15, 2025 (JP) 2025-066841

(51) Int. Cl. H10W 90/00

(52) U.S. Cl. CPC H10W 90/754; H10W 90/724

(57) ABSTRACT

A sensor system includes a light emitting element, a light receiving element, and a substrate on which the light emitting element and the light receiving element. The light receiving element receives light irradiated from the light emitting element. The light emitting element includes a first electrode and a second electrode. The substrate includes a first land to be electrically connected to the first electrode and a second land to be electrically connected to the second electrode. The substrate includes a conductive pattern located between the first land and the second land in a direction form the first land toward the second land. The first land and the conductive pattern are electrically connected.

### BACKGROUND

### Field of the Technology

The present disclosure relates to a sensor system which detects an object and an image forming apparatus provided therewith.

### Description of the Related Art

An optical sensor in which light is irradiated from a light emitting element mounted on a substrate to an irradiated portion, and the light transmitted through the irradiated portion or the light reflected by the irradiated portion is received by a light receiving element is known. In the optical sensor, unintended light (hereinafter, referred to as stray light) from the light emitting element may pass through the substrate, propagate inside the substrate, and then be incident on the light receiving element. According to Japanese Patent Application Laid-Open No. H11-354832, in order to suppress the stray light from being incident on the light receiving element, a configuration in which an entire area of the substrate is covered with copper foil is proposed.

### SUMMARY

The present disclosure is conceived under such a background, and an object of the present disclosure is to suppress a decrease in detection accuracy of a sensor system due to stray light.

In order to solve the aforementioned problems, the present disclosure is provided with the following configuration.

A sensor system comprising:
(1) A sensor system comprising: a first photoelectric element which is one of a light emitting element and a light receiving element; a second photoelectric element which is the other of the light emitting element and the light receiving element; and a substrate on which the first photoelectric element and the second photoelectric element are mounted, wherein the light receiving element receives light irradiated from the light emitting element, wherein the first photoelectric element includes a first electrode and a second electrode, wherein the substrate includes a first land to be electrically connected to the first electrode and a second land to be electrically connected to the second electrode, wherein the substrate includes a conductive pattern located between the first land and the second land in a direction form the first land toward the second land, and wherein the first land and the conductive pattern are electrically connected.
(2) An image forming apparatus provided with the sensor system according to (1), the image forming apparatus comprising: a cartridge provided with an accommodating portion configured to accommodate toner, wherein the light irradiated from the light emitting element is received by the light receiving element after reflected by or passing through the accommodating portion, wherein the light receiving element outputs a signal based on the light which is received, and wherein the image forming apparatus determines a toner amount in the accommodating portion based on the signal.
(3) An image forming apparatus provided with the sensor system according to (1), the image forming apparatus comprising: a conveying portion configured to convey a recording material along a conveyance passage, wherein the sensor system detects a surface state of the recording material conveyed by the conveying portion.
(4) An image forming apparatus provided with the sensor system according to (1), wherein the sensor system detects an optical density of an image formed on a recording material.
(5) An image forming apparatus provided with the sensor system according to (1), wherein the sensor system detects a hue of an image formed on a recording material.

Further features of the present invention will become apparent from the following description of exemplary embodiments with reference to the attached drawings. The following description of embodiments is described by way of example.

### BRIEF DESCRIPTION OF THE DRAWINGS

FIG. 1 is an outline view of an image forming apparatus in Embodiments 1 through 5.

FIG. 2 is a cross-sectional outline view of an optical sensor in the Embodiments 1 through 4.

FIG. 3 is a cross-sectional outline view of an optical sensor in the Embodiments 1 through 5.

FIG. 4, part (A), part (B), and part (C), includes plan views illustrating a vicinity of a light emitting element in the Embodiment 1.

FIG. 5 is a three-dimensional view illustrating the vicinity of the light emitting element in the Embodiment 1.

FIG. 6, part (A), part (B), and part (C), includes plan views illustrating a vicinity of a light emitting element in the Embodiment 2.

FIG. 7, part (A), part (B), and part (C), includes plan views illustrating a vicinity of a light receiving element in the Embodiment 3.

FIG. 8 is a three-dimensional view illustrating the vicinity of the light receiving element in the Embodiment 3.

FIG. 9, part (A), part (B), and part (C), includes plan views illustrating a vicinity of a light receiving element in the Embodiment 4.

FIG. 10 is an outline view of an image forming apparatus in Embodiments 6 through 9.

FIG. 11 is a cross-sectional outline view of an optical sensor and a process cartridge in the Embodiments 6 through 9.

FIG. 12 is a cross-sectional outline view of the optical sensor in the Embodiments 6 through 9.

FIG. 13 is a plan view of a substrate in the Embodiments 6 through 9.

### DESCRIPTION OF THE EMBODIMENTS

Hereinafter, Embodiments will be described in detail with reference to the accompanying drawings. Incidentally, the Embodiments below are not intended to limit the invention according to the claims. In the Embodiments, a plurality of characteristics are described, however, it is not necessarily all of these plurality of the characteristics are essential to the invention, and in addition, the plurality of the characteristics may be combined arbitrarily.

In description in the following Embodiments 1 through 5 and in each drawing, a vertical direction in a case in which an image forming apparatus is placed on a horizontal plane is defined as a V direction. A direction crossing the V direction and being a direction of a rotational axis of a photosensitive drum, which will be described below (rotational axis direction of the photosensitive drum), is defined as an H1 direction. A direction crossing both the V direction and the H1 direction is defined as an H2 direction. The H1 direction and the H2 direction are preferably horizontal directions. In addition, the H1 direction, the H2 direction, and the V direction are preferably perpendicular to each other.

### Embodiment 1

An optical sensor has various examples of application. For example, the optical sensor is used as a sensor upon detecting a remaining amount of toner in an image forming apparatus. Hereinafter, the image forming apparatus will be described.

### Image Forming Apparatus

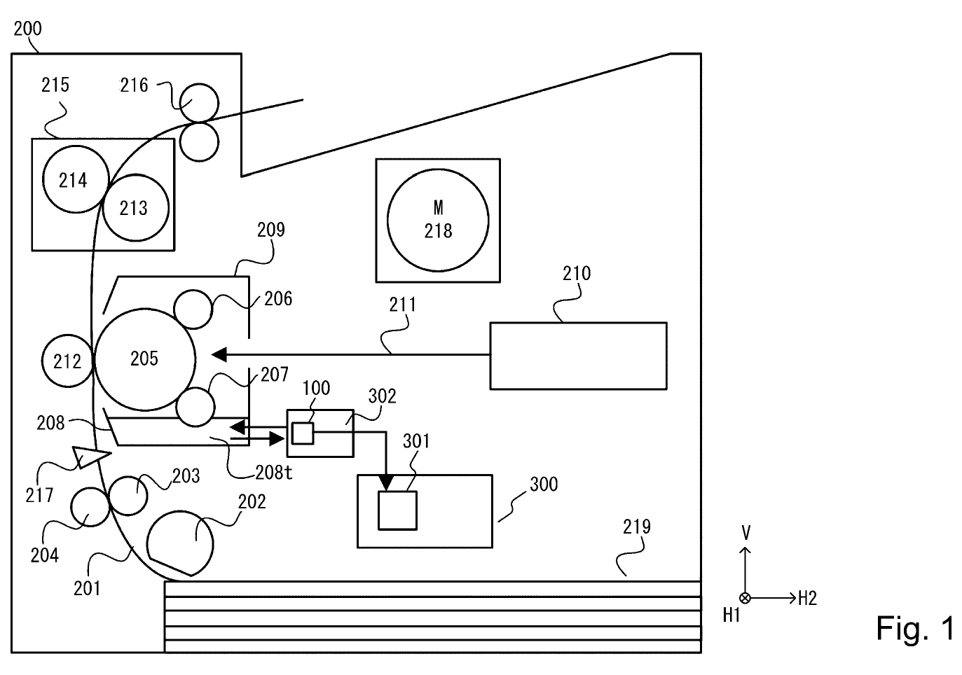

In FIG. 1, a configuration example of an image forming apparatus 200 is illustrated. When printing is started, the image forming apparatus 200 picks up a recording material (medium) 201 from a sheet feeding portion 219 by a sheet feeding roller 202, and the recording material 201 is conveyed by conveying rollers 203 and 204. When the conveyance of the recording material 201 is started, a leading end and a trailing end of the recording material 201 are detected by a detecting flag 217. By the detecting flag 217 detecting the leading end of the recording material 201, it becomes possible that a start timing for each electrophotographic process, which will be described next, is determined.

To a process cartridge 209 (cartridge), a photosensitive drum 205 as an image bearing member, a charging roller 206, a developing roller 207, and an accommodating portion 208 which accommodates toner 208t are provided. In other words, it may also be said that the process cartridge 209 includes the photosensitive drum 205, the charging roller 206, the developing roller 207, and the toner 208t. A high voltage is applied to the charging roller 206 along with the start of printing, and after the charging roller 206 uniformly charges the photosensitive drum 205, a scanning optical device 210 scans laser light 211 to an image forming area on the photosensitive drum 205. By the photosensitive drum 205 charged according to an image pattern and a high voltage applied to the developing roller 207, a toner image according to the image pattern is formed on the photosensitive drum 205. A high voltage is applied to a transfer roller 212, and the toner image is transferred to the recording material 201.

At this time, a remaining amount of the toner 208t in the process cartridge 209 is estimated based on an output signal of an optical sensor 100 which a toner remaining amount detecting unit 302 includes. Light irradiated from a light emitting element of the optical sensor 100 is received by a light receiving element of the optical sensor 100 after reflected by or passing through the accommodating portion 208. The light receiving element outputs a signal based on the light which is received, and the image forming apparatus determines a toner amount in the accommodating portion 208 (inside the accommodating portion) based on the signal. The optical sensor 100 is an example of a sensor system.

The toner 208t which the process cartridge 209 incudes is repeatedly being stirred inside a toner accommodating space. The toner 208t shields a light guide (151, which will be described below), which passes through the inside of the accommodating space, for a certain amount of time depending on a remaining amount of the toner (hereinafter, referred to as a toner remaining amount). The optical sensor 100, which the toner remaining amount detecting unit 302 includes, realizes incidence of the light to the light guide, receiving of the light of the irradiated light from the light guide, and signal output to an engine control unit 300, which are necessary for detection of a shielded time. An output destination of the output signal of the optical sensor 100 is a CPU 301, which the engine control unit 300 includes. The CPU 301 estimates the toner remaining amount based on the signal input from the optical sensor 100. When the toner remaining amount becomes small, a user is notified.

As to the recording material 201, onto which the toner image has been transferred, the toner 208t is fixed to the recording material 201 by a fixing device 215 including a heating device 213 and a pressing device 214, and by the recording material 201 being discharged by a discharge roller 216, image formation is completed. In addition, a motor 218 applies driving force to each unit including the fixing device 215. Incidentally, it may be a configuration in which two or more motors, which are driving sources applying the driving force to each unit, are used. In addition, in FIG. 1, the image forming apparatus 200 which forms a monochrome image is illustrated, however, the technical idea of the present disclosure is also applicable to an image forming apparatus which forms a full-color image.

Incidentally, the engine control unit 300 may include, besides the CPU 301 (Central Processing Unit), a ROM (Read Only Memory), a RAM (Random Access Memory), and a timer. The CPU 301 controls the image forming apparatus 200 by executing a program stored in advance in the ROM while using the RAM as a temporary working area. Upon performing the control of the image forming apparatus 200, the CPU 301 performs control of various types of timings using the timer. Incidentally, the engine control unit 300 may be provided with an ASIC (Application Specific Integrated Circuit) and/or an MPU (Micro Processing Unit). Numbers of the CPU 301, the timer, the ROM, and the RAM are not limited to one, but may be plural. In addition, as a storage medium, other storage media such as a hard disk and an optical disk may be used.

### Optical Sensor

In description for the following Embodiments 1 through 5 and in each drawing, a thickness direction of a substrate of the optical sensor 100 is defined as a Z direction. A direction crossing the Z direction and being an alignment direction of the light emitting element and the light receiving element, which will be described below, is defined as an X direction. The X direction is also widthwise directions of the light emitting element and the light receiving element. A direction crossing both the Z direction and the X direction is defined as a Y direction. The Y direction is also longitudinal directions of the light emitting element and the light receiving element. The X direction, the Y direction, and the Z direction are preferably perpendicular to each other. In addition, as necessary, directions of arrows X, Y, and Z illustrated in each drawing are expressed as a +X side, a +Y side, and a +Z side, respectively, and opposite sides thereof are expressed as a -X side, a -Y side, and a -Z side, respectively. In the present Embodiment, in the X direction, the light emitting element is disposed on the +X side with respect to the light receiving element. In other words, in the X direction, the light receiving element is disposed on the -X side with respect to the light emitting element.

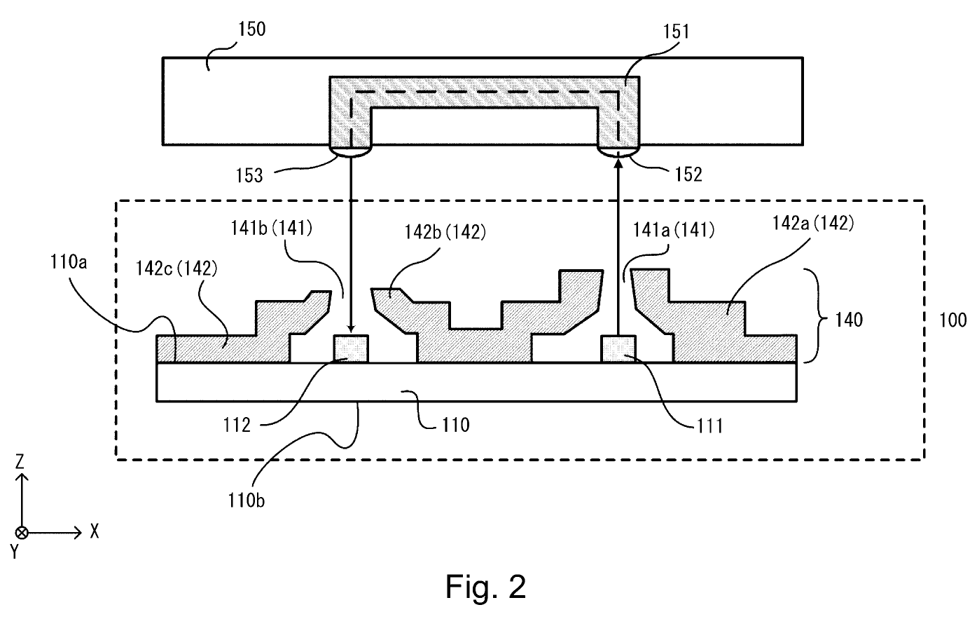

In FIG. 2, a cross-sectional outline view of the optical sensor 100 is illustrated. The light emitting element 111 is, for example, an LED (Light Emitting Diode) infrared rays emitting element. The light receiving element 112 is, for example, a phototransistor infrared rays receiving element. One of the light emitting element 111 and the light receiving element 112 is an example of a first photoelectric element, and the other of the light emitting element 111 and the light receiving element 112 is an example of a second photoelectric element. The light emitting element 111 and the light receiving element 112 are elements of bare chip type and are surface-mounted on the same surface of the substrate 110 so that center optical axes of the light emitting element 111 and the light receiving element 112 are approximately perpendicular to the surface of the substrate 110. In other words, the respective center optical axes of the light emitting element 111 and the light receiving element 112 are parallel to the Z direction. The substrate 110 is an example of a substrate on which the first photoelectric element and the second photoelectric element are mounted.

In the substrate 110, a surface on which the light emitting element 111 and the light receiving element 112 are mounted is defined as a mounting surface 110a, and a surface opposite to the mounting surface 110a is defined as a surface 110b. Incidentally, other electronic circuit components are also mounted on the substrate 110 but are omitted in FIG. 2. These unshown electronic circuit components are surface-mounted on the substrate 110.

In the mounting surface 110a of the substrate 110, on which the light emitting element 111 and the light receiving element 112 are mounted, an aperture 140, which is an optical aperture, is provided. The aperture 140 includes opening portions 141a and 141b, and a light shielding wall 142. The opening portions 141a and 141b may be collectively referred to as an opening portion 141. The light shielding wall 142 is provided on the mounting surface 110a so as to surround the light emitting element 111 and the light receiving element 112, respectively. Through the opening portion 141a, light output from the light emitting element 111 passes. Through the opening portion 141b, light arriving from an outside pass.

FIG. 2 is a cross-sectional view at a center position in the Y direction of the light emitting element 111 and the light receiving element 112. When the cross section in FIG. 2 is viewed, by the opening portions 141a and 141b being provided, the light shielding wall 142 is divided into light shielding walls 142a, 142b, and 142c. The light shielding wall 142a is provided on the +X side of the light emitting element 111. The light shielding wall 142b is provided on the -X side of the light emitting element 111 and the +X side of the light receiving element 112, in other words, between the light emitting element 111 and the light receiving element 112. The light shielding wall 142c is provided on the -X side of the light receiving element 112. The aperture 140 acts to stop down the light output from the light emitting element 111 and the light arriving from the outside.

On the +Z side of the optical sensor 100, a holding member 150 including a light guide 151 is provided. In other words, the light guide 151 is disposed opposite to the substrate 110. The holding member 150 holds the light guide 151, and it can also be said that the holding member 150 includes the light guide 151. The light guide 151 includes an incident end 152 and an emitting end 153. The output light of the light emitting element 111 passes through the opening portion 141a of the light shielding wall 142 and is emitted to the incident end 152 of the light guide 151. The light guided inside the light guide 151 (transmitted light) is radiated from the emitting end 153 of the light guide 151, passes through the opening portion 141b of the light shielding wall 142, and is incident on the light receiving element 112. The light receiving element 112 outputs a signal (voltage value) according to the light which is received.

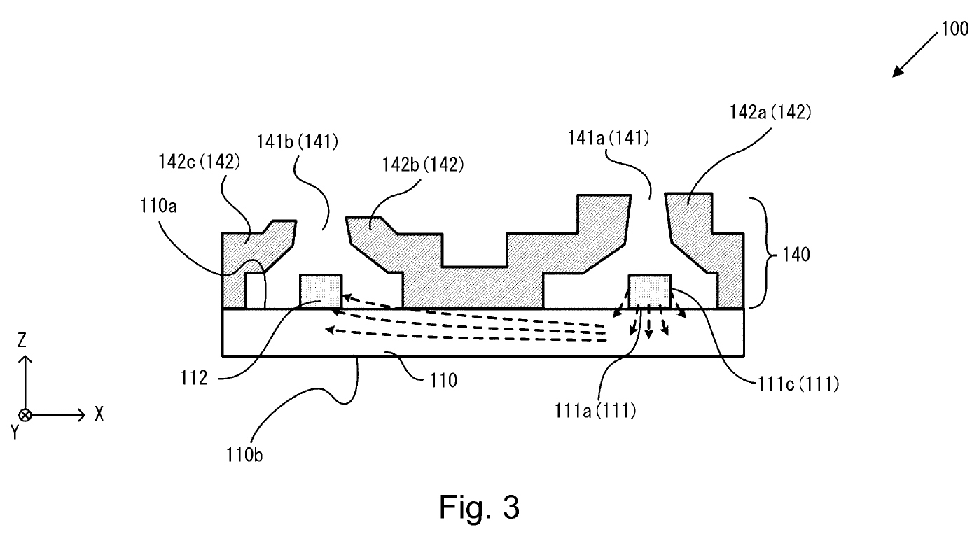

FIG. 3 is a view illustrating the optical sensor 100 in FIG. 2. As shown in FIG. 3, a part of the light output from the light emitting element 111 (indicated by broken line arrows in FIG. 3) does not pass through the opening portions 141a and 141b, but enters inside the substrate 110. The light which is not guided by the light guide 151 in this manner is referred to as stray light. The stray light, which has entered inside the substrate 110, travels in the -X direction, and is incident on the light receiving element 112. And since the light receiving element 112 outputs the signal according to a received light amount including the stray light, there is a possibility that detection accuracy of the optical sensor 100 decreases or the optical sensor 100 detects falsely. This is a problem that must be considered in the case in which the light receiving element and the light emitting element are mounted on the same substrate. Incidentally, in the present Embodiment, an example in which the light emitting element and the light receiving element are mounted on the same surface (mounting surface 110a) is described. However, even in a case in which the light emitting element and the light receiving element are mounted on different surfaces, for example, in a case in which the light emitting element is mounted on the mounting surface 110a and the light receiving element is mounted on the surface 110b, a similar problem occurs.

### Countermeasure Against the Stray Light

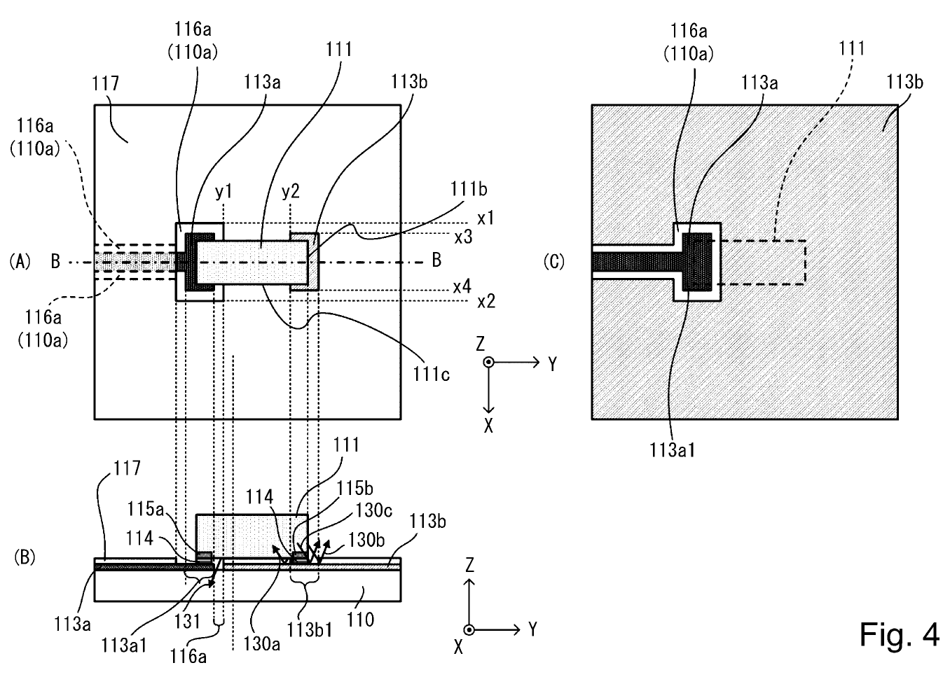

Part (A) of FIG. 4 is a plan view illustrating a vicinity of the light emitting element 111. Part (B) of FIG. 4 is a B-B cross-sectional view of Part (A) of FIG. 4. Part (C) of FIG. 4 is a plan view illustrating a copper foil area in the vicinity of the light emitting element 111, in which a resist 117 is unshown and the light emitting element 111 is illustrated by a broken line.

On the mounting surface 110a of the substrate 110, a pattern 113a and a pattern 113b made of copper foil are formed or laminated. The pattern 113a and the pattern 113b are not electrically connected to each other, and are not at the same potential. The pattern 113b is a conductive pattern (first conductive pattern) positioned, in a direction from a first land toward a second land, which will be described below, between the first land and the second land, and is an example of a conductive pattern (first conductive pattern) which the substrate includes. Incidentally, the direction from the first land toward the second land (first direction) is the -Y direction. The pattern 113a is electrically connected to the second land, is a pattern having conductivity, and is an example of a second conductive pattern which the substrate includes.

The light emitting element 111 includes an electrode 115a (second electrode), when a cross section in Part (B) of FIG. 4 is viewed, at an end portion thereof on the -Y side and an electrode 115b (first electrode) at an end portion thereof on the +Y side. Between the light emitting element 111 and the patterns 113a and 113b, solder 114 exists. By the solder 114, the electrode 115a of the light emitting element 111 and the pattern 113a are joined, and the electrode 115b and the pattern 113b are joined, so that the light emitting element 111 is electrically connected. The resist 117 is an insulation layer provided on an upper layer of the substrate 110 and the patterns 113a and 113b.

At a boundary between the pattern 113a and the pattern 113b, in order to separate potentials of the electrode 115a and a potential of the electrode 115b, an area in which the copper foil is not present and the mounting surface 110a of the substrate 110 is exposed (hereinafter, referred to as an insulation area 116a) is provided. The insulation area 116a is provided between the first conductive pattern and the second conductive pattern and is an example of an insulation area for insulating the first conductive pattern and the second conductive pattern.

In addition, a part of the patterns 113a and 113b formed on the substrate 110 is an area which is not covered by the resist 117, in other words, in which the copper foil is exposed (hereinafter, referred to as a land). Incidentally, an area in which the copper foil of the pattern 113a is exposed is defined as a land 113a1, and an area in which the copper foil of the pattern 113b is exposed is defined as a land 113b1. To the land 113a1, the electrode 115a provided on a bottom surface of the light emitting element 111 is soldered, and to the land 113b1, the electrode 115b provided on the bottom surface of the light emitting element 111 is soldered. The lands 113a1 and 113b1 include a portion contacting the solder 114. The land 113b1 is the first land to be electrically connected to the first electrode and is an example of the first land which the substrate includes. The land 113a1 is the second land to be electrically connected to the second electrode, and is an example of the second land which the substrate includes. At this time, the first land and the conductive pattern (first conductive pattern) are electrically connected.

By a periphery of the land 113a1 being surrounded by the insulation area 116a and the resist 117, it becomes less likely for the solder to spread to an outside of the land 113a1. In addition, by a periphery of the land 113b1 being surrounded by the resist 117, it becomes less likely for the solder to spread to an outside of the land 113b1. Therefore, it becomes less likely for mounting failure to occur in the vicinity of the lands 113a1 and 113b1.

Here, the patterns 113a and 113b of the copper foil have, against the light irradiated from the light emitting element 111, a high light shielding effect. Therefore, it is possible for the pattern 113a and the pattern 113b to effectively suppress the stray light via the substrate 110. On the other hand, the resist 117 generally has translucency and does not have high light shielding property. For example, a color of the resist 117 is green, etc.

Here, as shown in FIG. 3, the bottom surface of the light emitting element 111 (surface on which the electrodes 115a and 115b are provided) is defined as a bottom surface 111a. As shown in Part (A) of FIG. 4, a side surface of the light emitting element 111 on the +Y side is defined as a side surface 111b, and a side surface on the +X side is defined as a side surface 111c. In addition, as shown in Part (B) of FIG. 4, light traveling from the bottom surface 111a of the light emitting element 111 toward the substrate 110 is indicated by an arrow 130a. Light traveling from the side surface 111b of the light emitting element 111 toward the substrate 110 is indicated by an arrow 130b, and light traveling from the side surface 111c of the light emitting element 111 toward the substrate 110 is indicated by an arrow 130c. Incidentally, as for description below, the same applies to light traveling from a side surface on the -Y side and a side surface on the -X side of the light emitting element 111 toward the substrate 110.

Light traveling from the side surfaces 111b and 111c and the bottom surface 111a of the light emitting element 111 toward the substrate 110 as indicated by the arrows 130a through 130c in Part (B) of FIG. 4 is shielded, except for light passing through the insulation area 116a as indicated by an arrow 131, by the patterns 113a and 113b. This effect is exhibited not only in a case in which the patterns 113a and 113b are completely covered by the resist 117 as in FIG. 4, but also in a case in which the patterns 113a and 113b are partially covered by the resist 117.

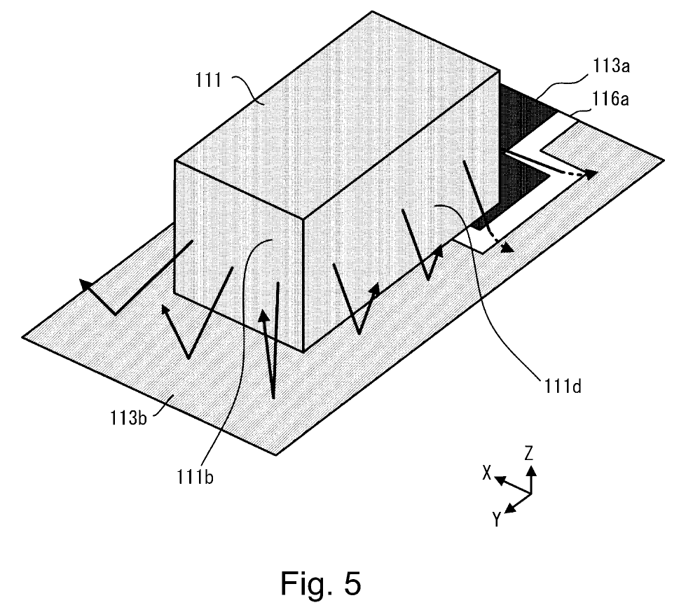

FIG. 5 is a three-dimensional view of the vicinity of the light emitting element 111 in a case in which the light shielding effect of the patterns 113a and 113b, which the Embodiment 1 includes, is maximized and the influence of the stray light is minimized. Here, the side surface of the light emitting element 111 on the -X side is defined as a side surface 111d. Incidentally, in FIG. 5, in order to describe the light shielding by the patterns 113a and 113b, the resist 117 is unshown. At this time, since the pattern 113b and the land 113b1 on the pattern 113b side are at the same potential, in other words, are continuous, it is not necessary to provide an insulation area around the land 113b1, and the pattern 113b and the land 113b1 can be connected without a gap. In addition, the insulation area is not required in the pattern 113b, so that it becomes possible to suppress entering of the light from the light emitting element 111 to the inside of the substrate 110 to the maximum. Therefore, it becomes possible to minimize the influence of the stray light. Due to the effects described above, without applying a separate light shielding material to the substrate 110, only with the patterns 113a and 113b of the copper foil, it becomes possible to effectively suppress the decrease in detection accuracy of the optical sensor 100 due to the stray light.

### Modified Example

In the Embodiment 1 described above, the example in which the pattern 113a is extended from the land 113a1 to the -Y side so as to go away from the light emitting element 111 is illustrated, however, it is not limited thereto. The pattern 113a may be designed so as to be extended from the land 113a1 to the + side or the - side of the X direction so as to go away from the light emitting element 111.

In the Embodiment 1 described above, the pattern 113b covered an entire area or a most part of an area of the mounting surface 110a of the substrate 110 excluding the pattern 113a and the insulation area 116a. However, an area (region) of the pattern 113b is not limited thereto. Here, as shown in Part (A) of FIG. 4, in the Y direction, a position of an end portion of the insulation area 116a on the +Y side is defined as y1, and a position of an end portion of the land 113b1 on the -Y side is defined as y2. In addition, in the X direction in part (A) of FIG. 4, a position of an end portion of the insulation area 116a on the -X side is defined as x1, a position of an end portion of the insulation area 116a on the +X side is defined as x2, a position of an end portion of the land 113b1 on the -X side is defined as x3, and a position of an end portion of the land 113b1 on the +X side is defined as x4. It is sufficient for the pattern 113b to pass (to be provided) at least between the land 113a1 and the land 113b1. Specifically, it is sufficient for the pattern 113b to be provided between the position y1 and the position y2 in the Y direction. In addition, in the X direction, it is sufficient for the pattern 113b to be provided between the position x1 and the position x2, or between the position x3 and the position x4. Further, the pattern 113b may include an area having trapezoidal shape which connects at least four points of (x1, y1), (x2, y1), (x3, y2), and (x4, y2). In addition, as for an area other than the area between the land 113a1 and the land 113b1, an area to which the pattern 113b is provided may be set according to directivity of the light emitting element 111.

As described above, according to the Embodiment 1, it becomes possible to suppress the decrease in detection accuracy of the sensor system due to the stray light.

### Embodiment 2

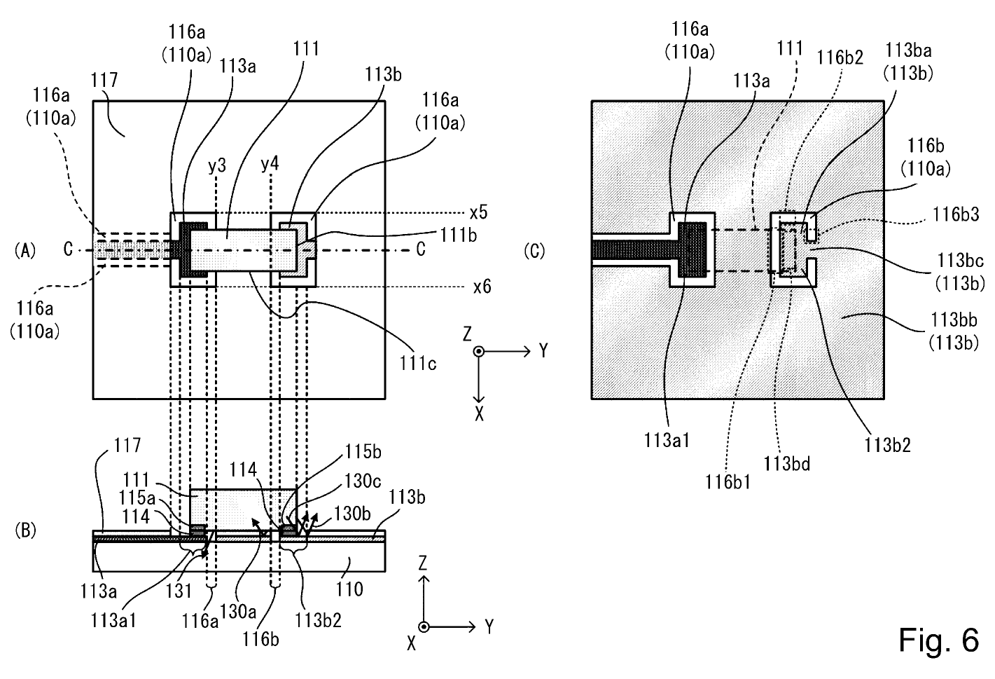

Part (A) of FIG. 6 is a plan view illustrating a vicinity of a light emitting element 111. Part (B) of FIG. 6 is a C-C cross-sectional view of the vicinity of the light emitting element 111. Part (C) of FIG. 6 is a plan view illustrating a copper foil area in the vicinity of the light emitting element 111, in which a resist 117 is unshown and the light emitting element 111 is illustrated by a broken line. In an Embodiment 2, the same reference numerals are attached to items which are the same as or similar to those in the Embodiment 1, and descriptions thereof are incorporated herein. Incidentally, Part (B) of FIG. 6 is view as viewed in a perpendicular direction of part (A) of FIG. 6, and vice versa.

Comparing FIGS. 4 and 6, in the Embodiment 2, an insulation area 116b is added (see Part (B) of FIGS. 4 and 6). The insulation area 116b is used as a means for improving accuracy of surface mounting such as adjustment of heat capacity and placement of a mark for adjusting a mounting position (hereinafter, referred to as an adjusting mark).

In Part (A) of FIG. 6, an area in which a copper foil of a pattern 113b is exposed is defined as a land 113b2. To the land 113b2, an electrode 115b provided on a bottom surface of the light emitting element 111 is soldered. The land 113b2 includes a portion contacting the solder 114. The land 113b2 is a first land to be electrically connected to a first electrode and is an example of a first land which the substrate includes.

As shown in Part (A) and Part (C) of FIG. 6, an entire periphery of the land 113b2 is not surrounded by the insulation area 116b, but a part of the land 113b2 is connected to the pattern 113b. In the Embodiment 2, the land 113b2, to which the electrode 115b of the light emitting element 111 is soldered, is an area in which the copper foil of the pattern 113b is exposed, and includes an area surrounded by the insulation area 116b in the pattern 113b. The insulation area 116b is an example of a non-formation area (first non-formation area), on which a pattern having conductivity is not formed and which the substrate includes. This non-formation area (first non-formation area) is provided between the first land and the conductive pattern in a first direction, and as viewed in the perpendicular direction, is overlapped with a first photoelectric element. In Part (C) of FIG. 6, the first non-formation area 116b1 is indicated by a dotted line. Incidentally, the first direction is a -Y direction, and the perpendicular direction is a Z direction. The perpendicular direction is a direction perpendicular to a mounting surface 110a of the substrate.

In addition, a part of the first conductive pattern (pattern 113b) overlapped with the first electrode (electrode 115b) as viewed in the perpendicular direction is defined as a first overlap portion 113bd. The substrate 110 is provided with a second non-formation area 116b2 on which a pattern having conductivity is not formed. The second non-formation area 116b2 is positioned at the same position as the first overlap portion 113bd in the first direction and is positioned at a different position from the first overlap portion 113bd in a second direction. Here, the second direction is a direction perpendicular to both the first direction and the perpendicular direction and is a -X direction. Further, the substrate 110 is provided with a third non-formation area 116b3 on which a pattern having conductivity is not formed. The third non-formation area 116b3 is upstream of the first overlap portion 113bd in the first direction and is positioned at the same position as the first overlap portion 113bd in the second direction.

The land 113a1 and the pattern 113a, and the land 113b2 and the pattern 113b are electrically connected, respectively. For this reason, a shape of the insulation area 116b may be arbitrarily determined regardless of the patterns 113a and 113b. Therefore, it becomes possible to realize the means for improving the accuracy of surface mounting with a necessary minimum insulation area. As described above, in the Embodiment 2, it becomes possible, while suppressing the stray light as much as possible with the copper foil pattern, to improve mountability.

### Modified Example

Here, in the pattern 113b, a portion forming the land 113b2 is defined as a portion 113ba, a portion not forming the land 113b2 is defined as a portion 113bb, and a portion connecting the portion 113ba and the portion 113bb is defined as a portion 113bc.

In the Embodiment 2 described above, the portion 113bc, which connects the portion 113ba forming the land 113b2 and the portion 113bb not forming the land 113b2, connects the portion 113ba and the portion 113bb on a +Y side of the land 113b2 in the Y direction. However, the portion 113bc may connect the portion 113ba and the portion 113bb on the -Y side of the land 113b2 in the Y direction. Further, the portion 113bc may connect the portion 113ba and the portion 113bb on a +X side or the -X side of the land 113b2 in the X direction.

In the Embodiment 2 described above, the pattern 113b covers an entire area or a most part of an area of the mounting surface 110a of the substrate 110 excluding the pattern 113a, an insulation area 116a, and the insulation area 116b. However, the pattern 113b in the Embodiment 2 is also not limited thereto. Here, in the Y direction in part (A) of FIG. 6, a position of an end portion of the insulation area 116a on the +Y side is defined as y3, and a position of an end portion of the insulation area 116b on the -Y side is defined as y4. In addition, in the X direction in part (A) of FIG. 6, a position of an end portion of the insulation area 116a and the insulation area 116b on the -X side is defined as x5, and a position of an end portion of the insulation area 116a and the insulation area 116b on the +X side is defined as x6. It is sufficient for the pattern 113b to pass (to be provided) at least between the land 113a1 and the land 113b2. Specifically, it is sufficient for the pattern 113b to be provided between the position y3 and the position y4 in the Y direction. In addition, it is sufficient for the pattern 113b to be provided between the position x5 and the position x6 in the X direction. As for an area other than the area between the land 113a1 and the land 113b2, an area on which the pattern 113b is provided may be set according to the directivity of the light emitting element 111.

As described above, according to the Embodiment 2, it becomes possible to suppress the decrease in detection accuracy of the sensor system due to the stray light.

### Embodiment 3

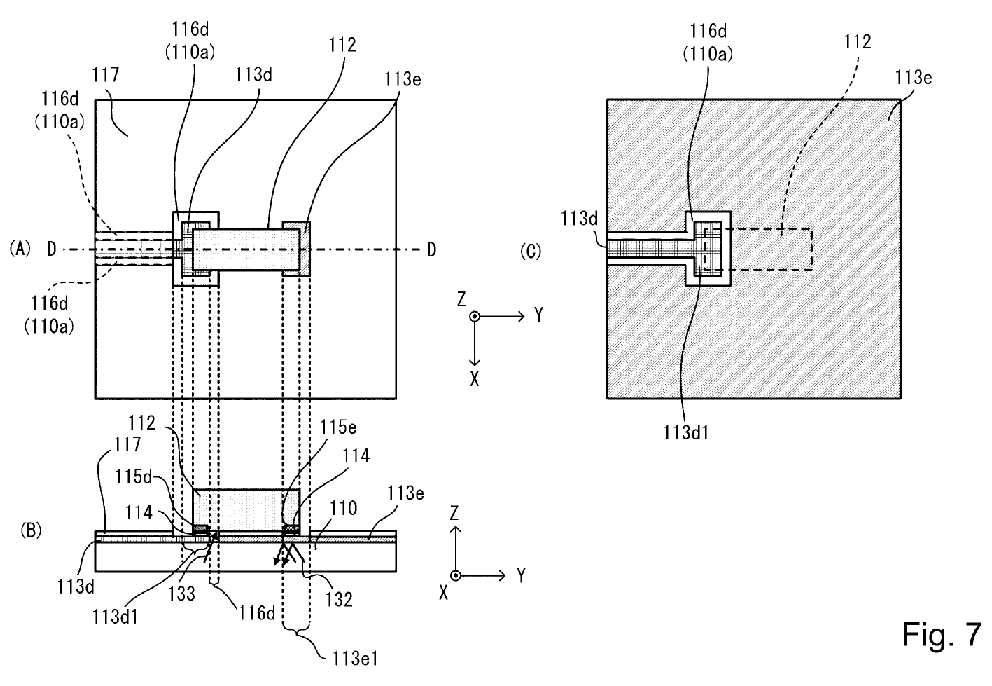

Part (A) of FIG. 7 is a plan view illustrating a vicinity of a light receiving element 112. Part (B) of FIG. 7 is a D-D cross-sectional view of the vicinity of the light receiving element 112. Part (C) of FIG. 7 is a plan view illustrating a copper foil area in the vicinity of the light receiving element 112, in which a resist 117 is unshown and the light receiving element 112 is indicated by a broken line. Part (A) through Part (C) of FIG. 7 indicate that the light emitting element 111 in Part (A) through Part (C) of FIG. 4 is replaceable with the light receiving element 112. In other words, the technical idea in the Embodiment 1 is applicable to the light receiving element 112. The light receiving element 112 includes an electrode 115d (second electrode), when a cross section in Part (B) of FIG. 7 is viewed, at an end portion thereof on a -Y side and an electrode 115e (first electrode) at an end portion thereof on a +Y side.

On a surface of the substrate 110, patterns 113d and 113e made of copper foil are formed or laminated. The pattern 113d and the pattern 113e are not electrically connected to each other and are not at the same potential. The pattern 113e is a conductive pattern (first conductive pattern) positioned, in a direction from a first land toward a second land, between the first land and the second land, and is an example of a conductive pattern (first conductive pattern) which the substrate includes. Incidentally, the direction from the first land toward the second land is the -Y direction. The pattern 113d is electrically connected to the second land, is a pattern having conductivity, and is an example of a second conductive pattern which the substrate includes.

The pattern 113d and the pattern 113e are separated by an insulation area 116d, in which the copper foil is absent. The insulation area 116d is provided between the first conductive pattern and the second conductive pattern and is an example of the insulation area for insulating the first conductive pattern and the second conductive pattern. On an upper layer of the patterns 113d and 113e, the resist 117 is provided. The electrode 115d of the light receiving element 112 is electrically connected, via the solder 114, to the pattern 113d. The electrode 115e of the light receiving element 112 is electrically connected, via the solder 114, to the pattern 113e.

An area in which the copper foil of the pattern 113d is exposed is defined as a land 113d1, and an area in which the copper foil of the pattern 113e is exposed is defined as a land 113e1. To the land 113d1, the electrode 115d provided on a bottom surface of the light receiving element 112 is soldered, and to the land 113e1, the electrode 115e provided on the bottom surface of the light receiving element 112 is soldered. The lands 113d1 and 113e1 include a portion contacting the solder 114. The land 113e1 is the first land to be electrically connected to the first electrode and is an example of the first land which the substrate includes. The land 113d1 is the second land to be electrically connected to the second electrode and is an example of the second land which the substrate includes. In this case, the first land and the conductive pattern (first conductive pattern) are electrically connected.

By a periphery of the land 113d1 being surrounded by the insulation area 116d and the resist 117, it becomes less likely for the solder to spread to an outside of the land 113d1. In addition, by a periphery of the land 113e1 being surrounded by the resist 117, it becomes less likely for the solder to spread to an outside of the land 113e1. Therefore, it becomes less likely for mounting failure to occur in the vicinity of the lands 113d1 and 113e1. Descriptions regarding a joining method of the light receiving element 112 and the lands 113d1 and 113e1, which the patterns 113d and 113e include, and light shielding effect, which the patterns 113d and 113e and the resist 117 have, are the same as those in the Embodiment 1, and thus will be omitted.

An arrow 132 is an example of the stray light output from the light emitting element 111, transmitted through the substrate 110, and traveling toward a side surface and the back surface of the light receiving element 112. The stray light indicated by the arrow 132 is shielded by the patterns 113d and 113e except for light passing through the insulation area 116d as indicated by an arrow 133, so that incident thereof on the light receiving element 112 is prevented. This effect is exhibited not only in a case in which the patterns 113d and 113e are completely covered by the resist 117 as in FIG. 7, but also in a case in which the patterns 113d and 113e are partially covered by the resist 117.

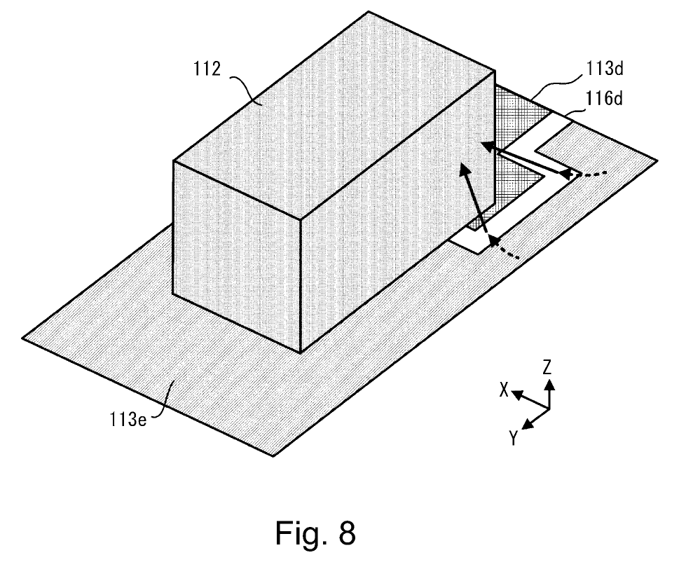

FIG. 8 is a three-dimensional view of the vicinity of the light receiving element 112 in a case in which the influence of the stray light is minimized by the light shielding effect of the patterns 113d and 113e, which the light receiving element 112 in the Embodiment 3 includes. In order to describe the light shielding by the patterns 113d and 113e, in FIG. 8, the resist 117 is unshown. In this case, since the pattern 113e and the land 113e1 connected to the pattern 113e are at the same potential, the pattern 113e and the land 113e1 can be connected without a gap. An insulation area is not required in the pattern 113e, so that it becomes possible to suppress irradiation of the light from the inside of the substrate 110 to the light receiving element 112 to the maximum. Therefore, it becomes possible to minimize the influence of the stray light. Due to the effects described above, without applying a separate light shielding material to the substrate 110, only with the copper foil, it becomes possible to suppress the decrease in detection accuracy of the optical sensor due to the stray light. Incidentally, points such that it is sufficient that the pattern 113e is provided between at least the land 113d1 and the land 113e1 is the same as in the Embodiment 1 and the Modified Example of the Embodiment 1 described above, so that description thereof will be omitted.

As described above, according to the Embodiment 3, it becomes possible to suppress the decrease in detection accuracy of the sensor system due to the stray light.

### Embodiment 4

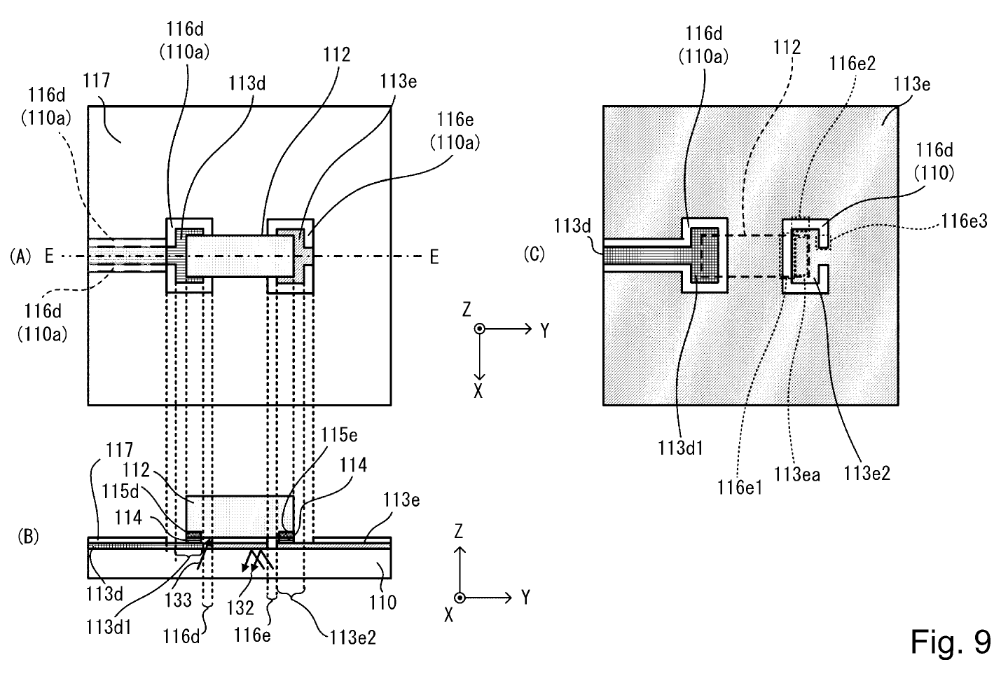

Part (A) of FIG. 9 is a plan view illustrating a vicinity of a light receiving element 112. Part (B) of FIG. 9 is an E-E cross-sectional view of the vicinity of the light receiving element 112. Part (C) of FIG. 9 is a plan view illustrating a copper foil area in the vicinity of the light receiving element 112, in which a resist 117 is unshown and the light receiving element 112 is indicated by a broken line. In an Embodiment 4, the same reference numerals are attached to items which are the same as or similar to those in the Embodiment 3, and descriptions thereof are incorporated herein.

Comparing FIGS. 7 and 9, in the Embodiment 4, an insulation area 116e is added. The insulation area 116e is used as a means for improving accuracy of surface mounting such as adjustment of heat capacity and placement of the mounting position adjusting mark. In the Embodiment 4, an area in which copper foil of a pattern 113e is exposed is defined as a land 113e2. To the land 113e2, an electrode 115e provided on a bottom surface of the light receiving element 112 is soldered. The land 113e2 includes a portion contacting the solder 114. The land 113e2, to which the electrode 115e of the light receiving element 112 is soldered, is an area in which the copper foil of the pattern 113e is exposed, and includes an area surrounded by the insulation area 116e in the pattern 113e. The land 113e2 is a first land to be electrically connected to a first electrode and is an example of the first land which a substrate includes.

The insulation area 116e is an example of a non-formation area (first non-formation area), on which a pattern having conductivity is not formed and which the substrate includes. This non-formation area (first non-formation area) is provided between the first land and a conductive pattern in a first direction, and as viewed in a perpendicular direction, is overlapped with a first photoelectric element. In Part (C) of FIG. 9, a first non-formation area 116e1 is indicated by a dotted line. Incidentally, the perpendicular direction is a Z direction.

In addition, a part of the first conductive pattern overlapped with the first electrode as viewed in the perpendicular direction is defined as a first overlap portion 113ea. The substrate 110 is provided with a second non-formation area 116e2 on which a pattern having conductivity is not formed. The second non-formation area 116e2 is positioned at the same position as the first overlap portion 113ea in the first direction and is positioned at a different position from the first overlap portion 113ea in a second direction. Here, the second direction is a direction perpendicular to both the first direction and the perpendicular direction and is a -X direction. Further, the substrate 110 is provided with a third non-formation area 116e3 on which a pattern having conductivity is not formed. The third non-formation area 116e3 is upstream of the first overlap portion 113ea in the first direction and is positioned at the same position as the first overlap portion 113ea in the second direction.

Since the land 113e2 and the pattern 113e are electrically connected, a shape of the insulation area 116e may be arbitrarily determined regardless of a pattern 113d and the pattern 113e. Therefore, it becomes possible to realize the means for improving surface mounting accuracy with a necessary minimum insulation area. As described above, in the Embodiment 4, it becomes possible, while suppressing stray light with the copper foil pattern as much as possible, to improve mountability. Incidentally, points such that it is sufficient that the pattern 113e is provided between at least the land 113d1 and the land 113e2 is the same as in the Embodiment 2 and the Modified Example of the Embodiment 2 described above, so that description thereof will be omitted. Also in the Embodiment 4, the stray light indicated by an arrow 132 is shielded by the patterns 113d and 113e except for light passing through the insulation area 116d (and/or the insulation area 116e) as indicated by an arrow 133, so that incident thereof on the light receiving element 112 is prevented.

As described above, according to the Embodiment 4, it becomes possible to suppress the decrease in detection accuracy of the sensor system due to the stray light.

### Embodiment 5

In the Embodiments described above, the example in which the optical sensor 100 is applied to the toner remaining amount detecting unit 302, which detects the toner remaining amount in the image forming apparatus 200, is described. However, this is merely an example. Examples of application of the optical sensor 100 including the light emitting element 111 and the light receiving element 112 are widely diverse.

### Application as a Media Sensor

Besides, the optical sensor 100 may be applied as a media sensor which detects a surface state of the recording material 201 by irradiating with light a surface of the recording material 201 and receiving the reflected light. The conveying rollers 203 and 204 in FIG. 1 are conveying portions, which the image forming apparatus provided with the sensor system is provided with, and are examples of a conveying portion which conveys the recording material along a conveyance passage. In this case, the optical sensor 100 as the sensor system detects the surface state of the recording material conveyed by the conveying portion.

Here, the surface state of the recording material 201 refers to information such as a depth and an interval of irregularities in a surface of the recording material 201. The information obtained by the optical sensor 100 as the media sensor is sent to the engine control unit 300. Then, based on the obtained information, the engine control unit 300 sets image forming conditions such as a conveying speed of the recording material 201, a transfer voltage upon transferring the toner image to the recording material 201, and a fixing temperature upon fixing the toner image to the recording material 201. In this manner, by setting the image forming conditions according to the surface state of the recording material 201, it becomes possible to form a high-quality image on the recording material 201.

### Application as a Density Sensor

In addition, as another example of application of the optical sensor 100, there is a density sensor. The density sensor is a sensor for checking whether optical density of the toner image formed on the recording material 201 falls within a predetermined range. In other words, the optical sensor 100 as the sensor system detects the optical density of the image formed on the recording material. It is sufficient for the density sensor to be disposed at a position at which the optical density of the toner image on the recording material 201 can be detected.

The density sensor is provided with a light emitting portion and a light receiving portion. The light receiving portion of the density sensor includes at least two light receiving portions for specular reflection light and diffuse reflection light. The density sensor is configured to irradiate with light a toner pattern for density detection formed on the recording material 201 and receive the reflected light. Information obtained by the density sensor is sent to the engine control unit 300. Then, based on the obtained information, it becomes possible for the engine control unit 300 to adjust density of the toner image by adjusting an image signal based on image data and an exposure amount to the photosensitive drum 205.

### Application as a Color Sensor

As a further example of application of the optical sensor 100, there is a color sensor. The color sensor is a sensor for checking whether hue of a color toner image formed on the recording material 201 falls within a predetermined range. In other words, the optical sensor 100 as the sensor system detects hue of an image formed on the recording material. It is sufficient that the color sensor is disposed at a position at which the hue of the color toner image on the recording material 201 can be detected.

The color sensor is provided with a light emitting portion, a light spectrally separating portion, and a light receiving portion. Incidentally, as the light receiving portion, a line sensor is preferable. The color sensor is configured to irradiate with light the color toner image formed on the recording material 201, and receive the reflected light. Information obtained by the color sensor is sent to the engine control unit 300. Then, based on the obtained information, it becomes possible for the engine control unit 300 to adjust the hue of the color toner image by adjusting an image signal based on image data and an exposure amount to the photosensitive drum 205.

In addition to the examples described above, there are examples in which the sensor system is applied as an optical sensor on which a light emitting element and a light receiving element are mounted, however, representative examples are described here. Even in all of the examples of application, by applying the Embodiments described above, it becomes possible to suppress stray light and improve detection accuracy of an optical sensor. In addition, to the image forming apparatus 200 in FIG. 1, some of the toner remaining amount detecting unit 302, the media sensor, the density sensor, the color sensor, etc. may be provided, or all of these may be provided.

As described above, according to the Embodiment 5, it becomes possible to suppress the decrease in detection accuracy of the sensor system due to the stray light.

### Embodiment 6

In description in the following Embodiments 6 through 9 and in each drawing, a vertical direction in a case in which an image forming apparatus is placed on a horizontal plane is defined as a V direction. A direction crossing the V direction and being a direction of a rotational axis of a photosensitive drum, which will be described below (rotational axis direction of the photosensitive drum), is defined as an H1 direction. A direction crossing both the V direction and the H1 direction is defined as an H2 direction. The H1 direction and the H2 direction are preferably horizontal directions. In addition, the H1 direction, the H2 direction, and the V direction are preferably perpendicular to each other.

### Image Forming Apparatus

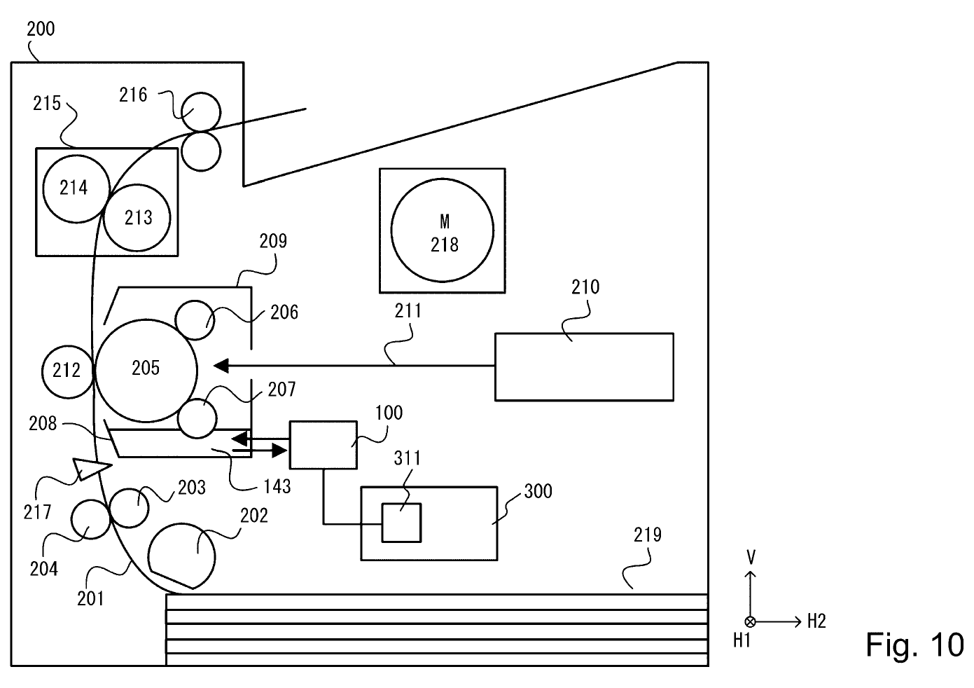

In FIG. 10, a configuration example of an image forming apparatus 200 is illustrated. When printing is started, the image forming apparatus 200 picks up a recording material 201 from a sheet feeding portion 219 by a sheet feeding roller 202, and the recording material 201 is conveyed by conveying rollers 203 and 204. When the conveyance of the recording material 201 is started, a leading end and a trailing end of the recording material 201 are detected by a detecting flag 217. By the detecting flag 217 detecting the leading end of the recording material 201, it becomes possible that a start timing for each electrophotographic process described next is determined.

To a process cartridge 209 (cartridge), a photosensitive drum 205 as an image bearing member, a charging roller 206, a developing roller 207, and an accommodating portion 208 which accommodates toner 143 are provided. In other words, it can also be said that the process cartridge 209 includes the photosensitive drum 205, the charging roller 206, the developing roller 207, the toner 143, and the accommodating portion 208. A high voltage is applied to the charging roller 206 simultaneously with the start of printing, and after the charging roller 206 uniformly charges the photosensitive drum 205, a scanning optical device 210 scans a laser light 211 to an image forming area on the photosensitive drum 205. By the photosensitive drum 205, which is charged according to an image pattern, and a high voltage, which is applied to the developing roller 207, a toner image according to the image pattern is formed on the photosensitive drum 205. A high voltage is applied to a transfer roller 212, and the toner image is transferred to the recording material 201.

At this time, a remaining amount of the toner 143 in the process cartridge 209 is estimated based on an output signal of an optical sensor 100. Light irradiated from a light emitting element of the optical sensor 100 is received by a light receiving element of the optical sensor 100 after reflected by or passing through the accommodating portion 208. The light receiving element outputs a signal based on the light, which is received, and the image forming apparatus 200 determines a toner amount in the accommodating portion 208 (inside the accommodating portion) based on the signal. The optical sensor 100 is an example of the sensor system.

The toner 143 which the process cartridge 209 includes is repeatedly being stirred inside a toner accommodating space. The toner 143 shields a light guide (151, which will be described below), which passes through the inside of the accommodating space, for a certain amount of time depending on a remaining amount of the toner (hereinafter, referred to as a toner remaining amount). The optical sensor 100 realizes incidence of the light to the light guide, receiving of the light of the irradiated light from the light guide, and signal output to an engine control unit 300, which are necessary for detection of a shielded time. An output destination of the output signal of the optical sensor 100 is a CPU 301 which the engine control unit 300 includes. The CPU 311 estimates the toner remaining amount based on the signal input from the optical sensor 100. When the toner remaining amount becomes small, a user is notified.

As to the recording material 201, onto which the toner image has been transferred, the toner 143 is fixed to the recording material 201 by a fixing device 215 including a heating device 213 and a pressing device 214, and by the recording material 201 being discharged by a discharge roller 216, image formation is completed. In addition, a motor 218 applies driving force to each unit including the fixing device 215. Incidentally, it may be a configuration in which two or more motors, which are driving sources applying the driving force to each unit, are used. In addition, in FIG. 10, the image forming apparatus 200 which forms a monochrome image is illustrated, however, the technical idea of the present disclosure is also applicable to an image forming apparatus which forms a full-color image.

Incidentally, the engine control unit 300 may include, besides a CPU 311 (Central Processing Unit), a ROM (Read Only Memory), a RAM (Random Access Memory), and a timer. The CPU 311 controls the image forming apparatus 200 by executing a program stored in advance in the ROM while using the RAM as a temporary working area. Upon performing the control of the image forming apparatus 200, the CPU 311 performs control of various types of timings using the timer. Incidentally, the engine control unit 300 may be provided with an ASIC (Application Specific Integrated Circuit) or an MPU (Micro Processing Unit). Numbers of the CPU 311, the timer, the ROM, and the RAM are not limited to one, but may be plural. In addition, as a storage medium, other storage media such as a hard disk and an optical disk may be used.

### Optical Sensor

In the description in the Embodiments 6 through 9 and in each drawing, a thickness direction of a substrate of the optical sensor 100 is defined as a Z direction. A direction crossing the Z direction and being an alignment direction of the light emitting element and the light receiving element, which will be described below, is defined as an X direction. The X direction is also widthwise directions of the light emitting element and the light receiving element. A direction crossing both the Z direction and the X direction is defined as a Y direction. The Y direction is also longitudinal directions of the light emitting element and the light receiving element. The X direction, the Y direction, and the Z direction are preferably perpendicular to each other. In addition, as necessary, directions of arrows X, Y, and Z illustrated in each drawing are expressed as a +X side, a +Y side, and a +Z side, respectively, and opposite sides thereof are expressed as a -X side, a -Y side, and a -Z side, respectively. In the present embodiment, in the X direction, the light emitting element is disposed on the +X side with respect to the light receiving element. In other words, in the X direction, the light receiving element is disposed on the -X side with respect to the light emitting element.

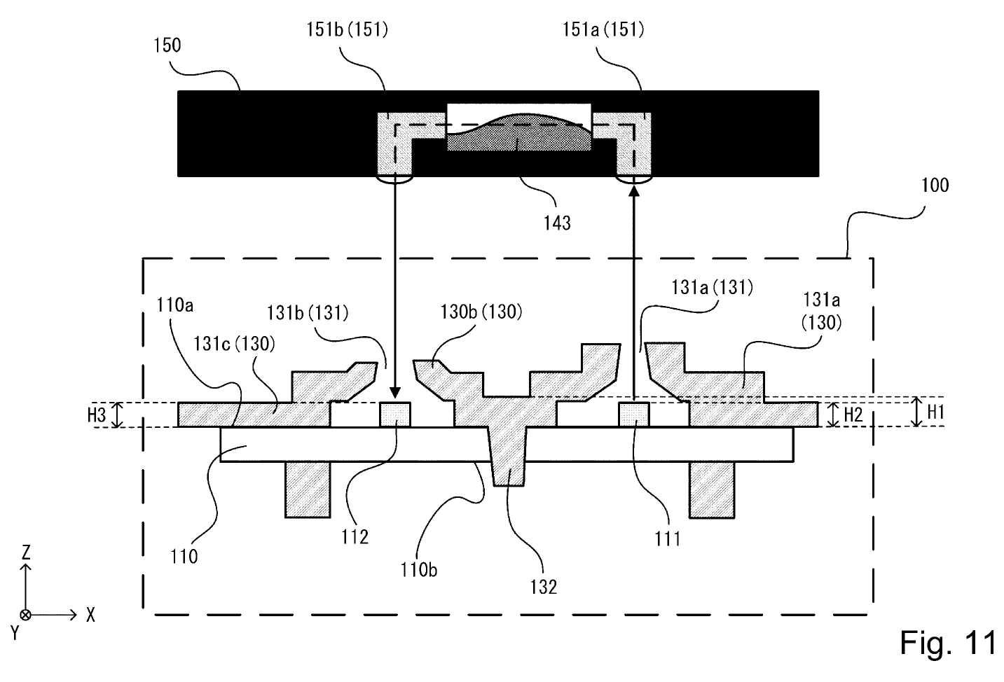

In FIG. 11, a cross-sectional outline view of the optical sensor 100 is illustrated. FIG. 11 is a cross-sectional view in a vicinity of centers of the light emitting element 111 and the light receiving element 112 in the Y direction. The light emitting element 111 is, for example, an LED (Light Emitting Diode) infrared rays emitting element. The light emitting element 111 is an example of a light emitting element provided with a first electrode and irradiates with light. The light receiving element 112 is, for example, a phototransistor infrared rays receiving element. The light receiving element 112 is an example of a light receiving element provided with a second electrode, and receives the light irradiated from the light emitting element and reflected by an irradiated portion or passing through the irradiated portion. The light emitting element 111 and the light receiving element 112 are elements of bare chip type and are surface mounted on the same surface of the substrate 110 so that center optical axes of the light emitting element 111 and the light receiving element 112 are approximately perpendicular to the surface of the substrate 110. In other words, the respective center optical axes of the light emitting element 111 and the light receiving element 112 are parallel to the Z direction. The substrate 110 is an example of a substrate provided with a mounting surface on which the light emitting element and the light receiving element are mounted and is a one side substrate.

In the substrate 110, a surface on which the light emitting element 111 and the light receiving element 112 are mounted is defined as a mounting surface 110a, and a surface opposite to the mounting surface 110a is defined as a surface 110b. Incidentally, other electronic circuit components are also mounted on the substrate 110 but are omitted in FIG. 11. These unshown electronic circuit components are surface-mounted on the substrate 110.

In the mounting surface 110a of the substrate 110, on which the light emitting element 111 and the light receiving element 112 are mounted, an aperture 130, which is an optical aperture, is provided. The aperture 130 includes opening portions 131a and 131b. The opening portions 131a and 131b may be collectively referred to as an opening portion 131. The aperture 130 is provided on the mounting surface 110a so as to surround the light emitting element 111 and the light receiving element 112, respectively.

When the cross section in FIG. 11 is viewed, by the opening portions 131a and 131b being provided, the aperture 130 is divided into apertures 130a, 130b, and 130c. The aperture 130a is provided on the +X side of the light emitting element 111. The aperture 130b is provided on the -X side of the light emitting element 111 and the +X side of the light receiving element 112, in other words, between the light emitting element 111 and the light receiving element 112. The aperture 130c is provided on the -X side of the light receiving element 112. The aperture 130 acts to stop down the light output from the light emitting element 111 and the light arriving from an outside. Incidentally, the aperture 130b is also a light shielding wall 132, which will be described below.

On the +Z side of the optical sensor 100, a holding member 150 including a light guide 151 is provided. In other words, the light guide 151 is disposed opposite to the substrate 110. The holding member 150 holds the light guide 151, and it can also be said that the holding member 150 includes the light guide 151. The light guide 151 includes an incident portion (end) 151a and an emitting portion (end) 151b. Through the incident portion 151a, light output from the light emitting element 111 passes. Through the emitting portion 151b, light arriving from the outside (guided by the light guide 151) passes. The output light of the light emitting element 111 passes through the opening portion 131a of the aperture 130 and is emitted to the incident portion 151a of the light guide 151. The light guided inside the light guide 151 (transmitted light) is radiated from the emitting portion 151b of the light guide 151, passes through the opening portion 131b of the aperture 130, and is incident on the light receiving element 112. The light receiving element 112 outputs a signal (voltage value) according to the light which is received.

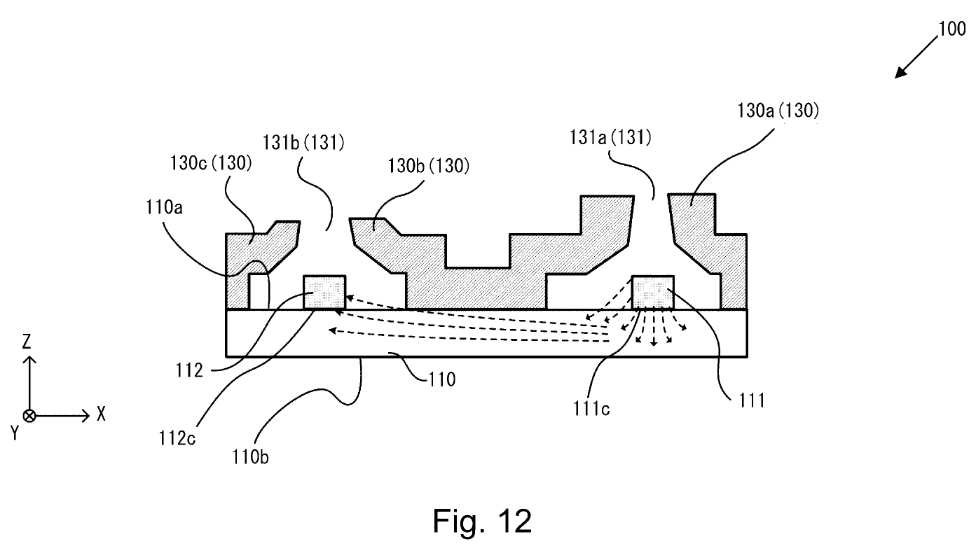

FIG. 12 is a view illustrating the optical sensor 100 in FIG. 11. FIG. 12 is a view of the substrate 110 viewed in the Y direction. As shown in FIG. 12, a part of the light output from the light emitting element 111 (indicated by broken line arrows in FIG. 12) does not pass through the opening portions 131a and 131b but enters inside the substrate 110. The light which is not guided by the light guide 151 in this manner is referred to as the stray light. The stray light, which has entered inside the substrate 110, travels in the -X direction, and is incident on the light receiving element 112. And since the light receiving element 112 outputs the signal according to a received light amount including the stray light, there is a possibility that detection accuracy of the optical sensor 100 decreases or the optical sensor 100 detects falsely. This is the problem that must be considered in the case in which the light receiving element and the light emitting element are mounted on the same substrate.

### Countermeasure Against the Stray Light

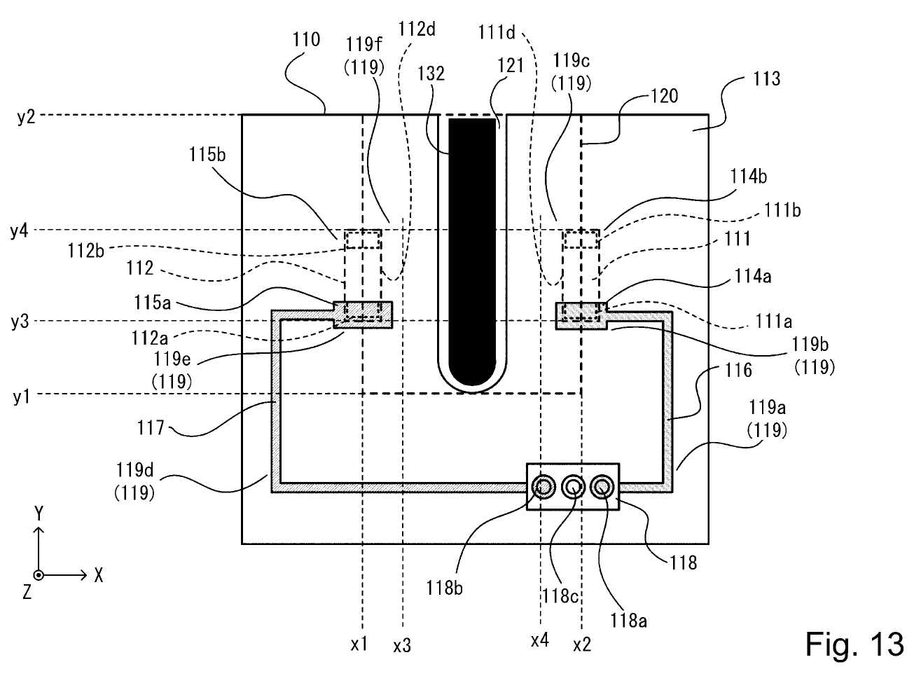

FIG. 13 illustrates a plan view of the substrate 110. Incidentally, the light shielding wall 132 in FIG. 13 illustrates a cross section at the mounting surface 110a viewed in the Z direction. In addition, in FIG. 13, the light emitting element 111 and the light receiving element 112 are illustrated by broken lines. On the mounting surface 110a of the substrate 110, a pattern 113 having conductivity made of copper foil is formed or laminated. The pattern 113 is a pattern having conductivity which the substrate is provided with and is an example of a conductive pattern insulated from a first pattern and a second pattern described later.

On the substrate 110, the light emitting element 111 and the light receiving element 112 are mounted. In addition, a slit 121 is provided in the substrate 110, and the light shielding wall 132 is fitted into the slit 121 (see FIG. 11). The light shielding wall 132 is an example of a light shielding wall which shields the light irradiated from the light emitting element to the light receiving element. Incidentally, as shown in FIG. 11, in the present Embodiment, it is configured as a portion into which the light shielding wall 132 is fitted, the slit 121 penetrating the substrate 110 is provided, however, it is not limited thereto. For example, a recessed portion, which does not penetrate the substrate 110, may be provided as a portion into which the light shielding wall 132 is inserted, it is sufficient that the light shielding wall 132 is insertable thereinto. In this case, as viewed in a perpendicular direction, the slit 121 and the recessed portion are positioned inside a first area, which will be described below. Incidentally, the perpendicular direction is a direction perpendicular to the mounting surface 110a, and is the Z direction.

Here, among surfaces which the light emitting element 111 includes, a surface opposite to the mounting surface 110a is defined as a bottom surface 111c (see FIG. 12). In addition, among the surfaces which the light emitting element 111 includes, a surface opposite to the light shielding wall 132, in other words, a surface on the -X side among two surfaces approximately perpendicular to the X direction as viewed in the Z direction is defined as a side surface 111d (see FIG. 13). In addition, among surfaces included in the light receiving element 112, a surface opposite to the mounting surface 110a is defined as a bottom surface 112c (see FIG. 12). Further, among the surfaces which the light receiving element 112 includes, a surface opposite to the light shielding wall 132, in other words, a surface on the +X side among two surfaces approximately perpendicular to the X direction as viewed in the Z direction is defined as a side surface 112d. The side surface 111d is an example of a first end portion, which is one end of the light emitting element in a parallel direction. The side surface 112d is an example of a second end portion, which is one end of the light receiving element in the parallel direction. Incidentally, the parallel direction is a direction in which the light emitting element 111 and the light receiving element 112 are aligned and is the X direction.

As shown in FIG. 13, the light emitting element 111 includes an electrode 111a (first electrode) at an end portion of the bottom surface 111c on the -Y side and includes an electrode 111b (third electrode) at an end portion of the bottom surface 111c on the +Y side. The electrode 111a of the light emitting element 111 is joined to a land 114a, and the electrode 111b of the light emitting element 111 is joined to a land 114b, respectively, by solder. The land 114a is a first land which the substrate is provided with and is an example of a first land to be electrically connected to the first electrode. The land 114b is a third land which the substrate is provided with and is an example of a third land to be electrically connected to the third electrode.

In addition, as shown in FIG. 13, the light receiving element 112 includes an electrode 112a (second electrode) at an end portion of the bottom surface 112c on the -Y side and includes an electrode 112b (fourth electrode) at an end portion of the bottom surface 112c on the +Y side. The electrode 112a of the light receiving element 112 is joined to a land 115a, and the electrode 112b of the light receiving element 112 is joined to a land 115b, respectively, by solder. The land 115a is a second land which the substrate is provided with and is an example of a second land to be electrically connected to the second electrode. The land 115b is a fourth land which the substrate is provided with and is an example of a fourth land to be electrically connected to the fourth electrode.

A pattern 116 is connected to the land 114a, and a pattern 117 is connected to the land 115a. The electrode 111a of the light emitting element 111 and the pattern 116 are joined, and the electrode 111b and the pattern 113 are joined, so that the light emitting element 111 is electrically connected. The pattern 116 is a first pattern which the substrate is provided with and is an example of a first pattern which is electrically connected to the first land and is a signal line through which a signal to be sent to the light emitting element is transmitted. The pattern 117 is a second pattern which the substrate is provided with and is an example of a second pattern which is electrically connected to the second land and is a signal line through which a signal to be sent from the light receiving element is transmitted. Incidentally, a resist may be provided as an insulation layer on an upper layer of each pattern.

On the substrate 110, a connector 118 is also mounted. The connector 118 is an example of a connector to which the first pattern and the second pattern are connected. The pattern 116 is connected to a connecting portion 118a of the connector 118, and the pattern 117 is connected to a connecting portion 118b of the connector 118, respectively, and a signal is sent to an outside through a bundle wire via the connector 118. In addition, the connector 118 is also connected to the pattern 113 via a connecting portion 118c. In FIG. 13, since the pattern 113 is a power source pattern, via the connector 118, power is supplied to the light emitting element 111 and the light receiving element 112 of the substrate 110.

Here, a pattern painted over a wide range with the copper foil on the mounting surface 110a like the pattern 113 (solid pattern) is generally used as a ground. Assuming that the pattern 113 is a ground pattern, a power pattern for power source to supply power to the light emitting element 111 and the light receiving element 112 becomes separately required. Then, by providing the power source pattern, it becomes necessary to provide an insulation area (insulation pattern), which will be described below, as well. In the present Embodiment, by using the pattern 113 as the power source pattern, there is no need to further provide the separate power source pattern or insulation area.

In order to prevent conduction between each land and pattern, around the lands 114a, 114b, 115a, and 115b and the patterns 116 and 117, insulation patterns 119, from which a conductive metal layer is removed, are provided. Specifically, an insulation pattern 119b is provided around the land 114a. An insulation pattern 119a is provided around the pattern 116. The insulation pattern 119a is an example of a first insulation area which is an insulative area and formed between the conductive pattern and the first pattern. Incidentally, the insulation pattern 119a and the insulation pattern 119b may be connected. An insulation pattern 119c is provided around the land 114b.

In addition, an insulation pattern 119e is provided around the land 115a. An insulation pattern 119d is provided around the pattern 117. The insulation pattern 119d is an example of a second insulation area which is an insulative area and formed between the conductive pattern and the second pattern. Incidentally, the insulation pattern 119d and the insulation pattern 119e may be connected. An insulation pattern 119f is provided around the land 115b.

Incidentally, the insulation pattern 119c is not continuous, and the land 114b is connected to the pattern 113 via the discontinuous portion of the insulation pattern 119c. Therefore, to the light emitting element 111, the power is supplied via the electrode 111b, the land 114b, and the pattern 113 (power source pattern). In addition, the insulation pattern 119f is also not continuous, and the land 115b is connected to the pattern 113 via the discontinuous portion of the insulation pattern 119f. Therefore, also to the light receiving element 112, the power is supplied via the electrode 112b, the land 115b, and the pattern 113 (power source pattern). It is sufficient that the conductive pattern is electrically connected to at least one of the third land and the fourth land. In addition, it is sufficient that the conductive pattern includes the power source pattern to supply the power to at least one of the light emitting element and the light receiving element.

Incidentally, in FIG. 13, the insulation pattern 119c is provided around the land 114b, and the insulation pattern 119f is provided around the land 115b, however, it is not limited thereto. Only one of the insulation pattern 119c and the insulation pattern 119f may be provided, or both insulation patterns may be omitted.

Since the insulation pattern 119 is an area from which the copper foil is removed (hereinafter, referred to as a copper foil removed area), light may pass through. Therefore, by the light emitted from the light emitting element 111 entering inside the substrate 110 as the stray light, or the stray light inside the substrate 110 being emitted to an outside of the substrate 110, the stray light may reach the light receiving element 112, and there is a possibility that detection accuracy of the optical sensor 100 decreases. In addition, since the slit 121 and the light shielding wall 132 are provided in the substrate 110, it is prevented that the stray light reaches the light receiving element 112 directly from the light emitting element 111. However, there is a possibility that the stray light entering inside the substrate 110 goes around the slit 121 and reaches the light receiving element 112. In order to prevent such entering of the stray light into the substrate 110 and emission from the substrate 110, in the Embodiment 6, a pattern prohibited area 120 is provided.

### Pattern Prohibited Area

Here, in the X direction, a position passing through a center of the light receiving element 112 is defined as x1, and a position passing through a center of the light emitting element 111 is defined as x2. Of two end portions of the insulation pattern 119f in the X direction, a position of the end portion closer to the light shielding wall 132 is defined as x3, and of two end portions of the insulation pattern 119c in the X direction, a position of the end portion closer to the light shielding wall 132 is defined as x4. Incidentally, in FIG. 13, the position x3 is, of two end portions of the insulation pattern 119e in the X direction, also a position of the end portion closer to the light shielding wall 132. In addition, the position x4 is, of two end portions of the insulation pattern 119b in the X direction, also a position of the end portion closer to the light shielding wall 132. In the X direction, in a case in which positions of respective end portions on closer sides to the light shielding wall 132 of the insulation pattern 119e and the insulation pattern 119f are different, it is sufficient that a position of the end portion closer to the light shielding wall 132 is defined as x3. Similarly, in the X direction, in a case in which positions of respective end portions on closer sides to the light shielding wall 132 of the insulation pattern 119b and the insulation pattern 119c are different, it is sufficient that a position of the end portion closer to the light shielding wall 132 is defined as x4.

In addition, in the Y direction, a position of an end portion of the slit 121 on the -Y side is defined as y1, and a position of an end portion thereof on the +Y side is defined as y2. Of two end portions of the light receiving element 112 in the Y direction, a position of the end portion on the electrode 112a side is defined as y3, and of the two end portions of the light receiving element 112 in the Y direction, a position of the end portion on the electrode 112b side is defined as y4. Incidentally, the position y3 is, of two end portions of the light emitting element 111 in the Y direction, also a position of the end portion on the electrode 111a side. In addition, the position y4 is, of the two end portions of the light emitting element 111 in the Y direction, also a position of the end portion on the electrode 111b side.

As shown in FIG. 13, the pattern prohibited area 120 is, in the X direction, an area from the center of the light emitting element 111 to the center of the light receiving element 112, in other words, an area from the position x1 to the position x2 (first area). In addition, the pattern prohibited area 120 is, in the Y direction, an area which includes at least the entire slit 121, in other words, an area from the position y1 to the position y2. In this case, the pattern prohibited area 120 becomes an area having rectangular shape defined by (x1, y1), (x1, y2), (x2, y1), and (x2, y2). In the pattern prohibited area 120, the insulation pattern 119a and the insulation pattern 119d are not positioned.

Further, the pattern prohibited area 120 may be the following area. That is, for example, the pattern prohibited area 120 may be, in the X direction, an area from the side surface 112d of the light receiving element 112 to the side surface 111d of the light emitting element 111. The area from the side surface 112d to the side surface 111d is, an example of a first area which is an area on the substrate sandwiched between the first end portion and the second end portion as viewed in the perpendicular direction. In this case, as viewed in the perpendicular direction, the first pattern and the second pattern are not positioned in the first area. In addition, for example, the pattern prohibited area 120 may be, in the X direction, an area from the position x3 to the position x4 described above. Also in this case, as viewed in the perpendicular direction, the pattern 116 and the pattern 117 are not positioned in the area from the position x3 to the position x4.

Here, an area sandwiched between the first end portion and the second end portion in the parallel direction as viewed in the perpendicular direction and where the slit 121 (or the recessed portion) is positioned in a first direction is defined as a second area. Incidentally, the first direction is a direction perpendicular to both the parallel direction and the perpendicular direction and is the Y direction. An area sandwiched by the side surface 111d and the side surface 112d in the X direction, and from the position y1 to the position y2 is an example of the second area. In addition, the pattern prohibited area 120 may also be an example of the second area. Furthermore, an area sandwiched by the side surface 111d and the side surface 112d in the X direction, and from the position y3 to the position y4 may also be an example of the second area. In the Y direction, it is sufficient that at least the light emitting element 111 and the light receiving element 112 are included. In these cases, the first pattern and the second pattern are not positioned in the second area.

Here, a height of the light shielding wall 132 from the mounting surface 110a is defined as H1 (first length), a height of the light emitting element 111 from the mounting surface 110a is defined as H2 (second length), and a height of the light receiving element 112 from the mounting surface 110a is defined as H3 (third length) (see FIG. 11). In this case, the height H1 is higher (longer) than the height H2 and the height H3 (H1 > H2, H1 > H3), and as viewed in the perpendicular direction, at least a part of the light shielding wall 132 is positioned in the first area described above. Incidentally, in a case in which the height of the light shielding wall 132 is not constant as in FIG. 11, a lowest height among a plurality of heights, which the light shielding wall 132 includes, is used as the height H1.

Here, if a signal line pattern is provided in the pattern prohibited area 120, an insulation pattern accompanying the signal line pattern in the pattern prohibited area 120 exists in a vicinity of the light emitting element 111 and light receiving element 112 area. Then, a light amount of the stray light entering inside the substrate 110 or emitted from the substrate 110 via the insulation pattern 119, which is provided in the pattern prohibited area 120, increases. Therefore, the pattern prohibited area 120 is provided, and it is configured to prohibit to provide the signal line pattern in the pattern prohibited area 120. In other words, in the optical sensor 100 in the Embodiment 6, as viewed in the perpendicular direction, each pattern is designed so that the first insulation area and the second insulation area are not positioned in the first area. By this, it becomes possible to prevent the decrease in detection accuracy of the optical sensor 100 due to the stray light.

As described above, according to the Embodiment 6, it becomes possible to suppress the decrease in detection accuracy of the sensor system due to the stray light.

### Embodiment 7

### Application as a Media Sensor

Besides, the optical sensor 100 may be applied as a media sensor which detects the surface state of the recording material 201 by irradiating with light the surface of the recording material 201 and receiving the reflected light. The conveying rollers 203 and 204 are examples of conveying portions, which the image forming apparatus provided with the sensor system is provided with and which conveys the recording material along the conveyance passage. In this case, the optical sensor 100 as the sensor system detects the surface state of the recording material conveyed by the conveying portion.

Here, the surface state of the recording material 201 refers to the information such as a depth and an interval of the irregularities in the surface of the recording material 201. The information obtained by the optical sensor 100 as the media sensor is sent to the engine control unit 300. Then, based on the obtained information, the engine control unit 300 sets the image forming conditions such as a conveying speed of the recording material 201, a transfer voltage upon transferring the toner image to the recording material 201, and a fixing temperature upon fixing the toner image to the recording material 201. In this manner, by setting the image forming conditions according to the surface state of the recording material 201, it becomes possible to form a high-quality image on the recording material 201.

As described above, according to the Embodiment 7, it becomes possible to suppress the decrease in detection accuracy of the sensor system due to the stray light.

### Embodiment 8

### Application as a Density Sensor

In addition, as an example of application of the optical sensor 100, there is the density sensor. The density sensor is a sensor for checking whether the optical density of the toner image formed on the recording material 201 falls within a predetermined range. In other words, the optical sensor 100 as the sensor system detects the optical density of the image formed on the recording material. The density sensor is provided with a light emitting portion and a light receiving portion. The light receiving portion of the density sensor includes at least two light receiving portions for specular reflection light and diffuse reflection light. The density sensor is configured to irradiate with light a toner pattern for density detection formed on the recording material 201 and receive the reflected light. Information obtained by the density sensor is sent to the engine control unit 300. Then, based on the obtained information, it becomes possible for the engine control unit 300 to adjust density of the toner image by adjusting the image signal based on image data and the exposure amount to the photosensitive drum 205.

As described above, according to the Embodiment 8, it becomes possible to suppress the decrease in detection accuracy of the sensor system due to the stray light.

### Embodiment 9

### Application as a Color Sensor

As a further example of application of the optical sensor 100, there is a color sensor. The color sensor is a sensor for checking whether hue of a color toner image formed on the recording material 201 falls within a predetermined range. In other words, the optical sensor 100 as the sensor system detects hue of an image formed on the recording material. The color sensor is provided with a light emitting portion, a light spectrally separating portion, and a light receiving portion. Incidentally, as the light receiving portion, a line sensor is preferable. The color sensor is configured to irradiate with light the color toner image formed on the recording material 201 and receive the reflected light. Information obtained by the color sensor is sent to the engine control unit 300. Then, based on the obtained information, it becomes possible for the engine control unit 300 to adjust the hue of the color toner image by adjusting the image signal based on image data and the exposure amount to the photosensitive drum 205.

In addition to the Embodiments described above, there are examples in which the sensor system is applied as an optical sensor, on which a light emitting means and a light receiving means are mounted, however, representative examples are described here. Even in all of the examples of application, by applying the Embodiments described above, it becomes possible to suppress the stray light, and improve the detection accuracy of the optical sensor. In addition, the image forming apparatus 200 may be provided with some of the toner remaining amount detecting unit 302, the media sensor, the density sensor, and the color sensor, or may be provided with all of these.

As described above, according to the Embodiment 9, it becomes possible to suppress the decrease in detection accuracy of the sensor system due to the stray light.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2025-066840 filed on Apr. 15, 2025 and Japanese Patent Application No.2025-066841 filed on Apr. 15, 2025, which are hereby incorporated by reference herein in its entirety.

What is claimed is:

1. A sensor system comprising:
a first photoelectric element which is one of a light emitting element and a light receiving element;
a second photoelectric element which is the other of the light emitting element and the light receiving element; and
a substrate on which the first photoelectric element and the second photoelectric element are mounted,
wherein the light receiving element receives light irradiated from the light emitting element,
wherein the first photoelectric element includes a first electrode and a second electrode,
wherein the substrate includes a first land to be electrically connected to the first electrode and a second land to be electrically connected to the second electrode,
wherein the substrate includes a conductive pattern located between the first land and the second land in a direction from the first land toward the second land, and
wherein the first land and the conductive pattern are electrically connected.

2. The sensor system according to claim 1, wherein when the conductive pattern is defined as a first conductive pattern, the substrate includes a second conductive pattern which is electrically connected to the second land and is a pattern having conductivity, and
wherein between the first conductive pattern and the second conductive pattern, an insulation area for insulating the first conductive pattern and the second conductive pattern is provided.

3. The sensor system according to claim 2, wherein when the direction is defined as a first direction and a direction perpendicular to a mounting surface of the substrate is defined as a perpendicular direction, the substrate includes a non-formation area on which the pattern having conductivity is not formed and the non-formation area is provided between the first land and the conductive pattern in the first direction, and
wherein as viewed in the perpendicular direction, the non-formation area overlaps the first photoelectric element.

4. The sensor system according to claim 3, wherein when the non-formation area is defined as a first non-formation area, a direction perpendicular to both the first direction and the perpendicular direction is defined as a second direction and a part of the first conductive pattern overlapped with the first electrode as viewed in the perpendicular direction is defined as a first overlap portion, the substrate is provided with a second non-formation area on which the pattern having conductivity is not formed, and
wherein the second non-formation area is positioned at the same position as the first overlap portion in the first direction and is positioned at a different position from the first overlap portion in the second direction.

5. The sensor system according to claim 4, wherein the substrate is provided with a third non-formation area on which the pattern having conductivity is not formed, and
wherein the third non-formation area is upstream of the first overlap portion in the first direction and is positioned at the same position as the first overlap portion in the second direction.

6. The sensor system according to claim 1, further comprising a light shielding wall provided between the light emitting element and the light receiving element.

7. An image forming apparatus provided with the sensor system according to claim 1, the image forming apparatus comprising:
a cartridge provided with an accommodating portion configured to accommodate toner,
wherein the light irradiated from the light emitting element is received by the light receiving element after being reflected by or being transmitted through the accommodating portion,
wherein the light receiving element outputs a signal based on the light which is received, and
wherein the image forming apparatus determines a toner amount in the accommodating portion based on the signal.

8. An image forming apparatus provided with the sensor system according to claim 1, the image forming apparatus comprising:
a conveying portion configured to convey a recording material along a conveyance passage,
wherein the sensor system detects a surface state of the recording material conveyed by the conveying portion.

9. An image forming apparatus provided with the sensor system according to claim 1, wherein the sensor system detects an optical density of an image formed on a recording material.

10. An image forming apparatus provided with the sensor system according to claim 1, wherein the sensor system detects a hue of an image formed on a recording material.

11. A sensor system comprising:
a light emitting element provided with a first electrode and configured to irradiate light;
a light receiving element provided with a second electrode and configured to receive the light irradiated from the light emitting element and reflected by or passing through an irradiated portion; and
a substrate provided with a mounting surface on which the light emitting element and the light receiving element are mounted,
wherein the substrate includes a first land to be electrically connected to the first electrode and a second land to be electrically connected to the second electrode,
wherein the substrate includes a first pattern which is electrically connected to the first land and which is a signal line through which a signal, to be sent to the light emitting element, is transmitted,
wherein the substrate includes a second pattern which is electrically connected to the second land and which is a signal line through which a signal, to be sent from the light receiving element, is transmitted, and
wherein when a direction where the light emitting element and the light receiving element are aligned is defined as a parallel direction, one end of the light emitting element in the parallel direction is defined as a first end portion, one end of the light receiving element in the parallel direction is defined as a second end portion, and an area on the substrate sandwiched between the first end portion and the second end portion as viewed in a perpendicular direction perpendicular to the mounting surface is defined as a first area, the first pattern and the second pattern are not positioned in the first area as viewed in the perpendicular direction.

12. The sensor system according to claim 11, wherein the substrate is provided with a conductive pattern which is a pattern having conductivity and is insulated from the first pattern and the second pattern,
wherein between the conductive pattern and the first pattern, a first insulation area which is an insulative area is formed,
wherein between the conductive pattern and the second pattern, a second insulation area which is an insulative area is formed, and
wherein as viewed in the perpendicular direction, the first insulation area and the second insulation area are not positioned in the first area.

13. The sensor system according to claim 11, wherein the substrate is a single- sided substrate.

14. The sensor system according to claim 12, wherein the light emitting element is provided with a third electrode,
wherein the light receiving element is provided with a fourth electrode,
wherein the substrate is provided with a third land to be electrically connected to the third electrode and a fourth land to be electrically connected to the fourth electrode, and
wherein the conductive pattern is electrically connected to at least one of the third land and the fourth land.

15. The sensor system according to claim 14, wherein the conductive pattern includes a power source pattern to supply power to at least one of the light emitting element and the light receiving element.

16. The sensor system according to claim 11, further comprising a light shielding wall configured to shield the light irradiated from the light emitting element from reaching the light receiving element,
wherein when a height of the light shielding wall from the mounting surface is defined as a first length, a height of the light emitting element from the mounting surface is defined as a second length, and a height from the light receiving element of the mounting surface is defined as a third length, the first length is longer than the second length and the third length, and
wherein as viewed in the perpendicular direction, at least a part of the light shielding wall is positioned in the first area.

17. The sensor system according to claim 16, wherein the substrate is formed with a recessed portion into which the light shielding wall is inserted, and
wherein as viewed in the perpendicular direction, the recessed portion is positioned in the first area.

18. The sensor system according to claim 17, wherein when a direction perpendicular to both the parallel direction and the perpendicular direction is defined as a first direction and an area sandwiched between the first end portion and the second end portion in the parallel direction as viewed in the perpendicular direction and where the recessed portion is positioned in the first direction is defined as a second area, the first pattern and the second pattern are not positioned in the second area.

19. The sensor system according to claim 11, further comprising a connector to which the first pattern and the second pattern are connected.

20. An image forming apparatus provided with the sensor system according to claim 11, the image forming apparatus comprising:
a cartridge provided with an accommodating portion configured to accommodate toner,
wherein the light irradiated from the light emitting element is received by the light receiving element after being reflected by or being transmitted through the accommodating portion,
wherein the light receiving element outputs a signal based on the light which is received, and
wherein the image forming apparatus determines a toner amount in the accommodating portion based on the signal.
